(19) United States
(12) Patent Application Publication
(10) Pub. No.: US 2026/0182207 A1
(43) Pub. Date: Jun. 25, 2026

(54) DISPLAY DEVICE

(71) Applicant: LG Display Co., Ltd., Seoul (KR)

(72) Inventors: MiJin HAN, Seoul (KR); SunBok SONG, Gwangmyeong-si (KR); Daeyun KIM, Seoul (KR)

(73) Assignee: LG Display Co., Ltd., Seoul (KR)

(21) Appl. No.: 19/401,996

(22) Filed: Nov. 26, 2025

(30) Foreign Application Priority Data
Dec. 23, 2024 (KR) 10-2024-0194091

(51) Int. Cl. H10K 59/80; H10K 102/00

(52) U.S. Cl. CPC H10K 59/872; H10K 59/873; H10K 2102/311

(57) ABSTRACT

A display device according to one or more examples includes a cover window, a flexible display panel disposed on a rear surface of the cover window, a metal plate disposed on a rear surface of the flexible display panel, and a plurality of first reinforcement layers which overlaps the cover window and is formed of a different material from the metal plate. A rear surface of the metal plate and rear surfaces of the plurality of reinforcement layers are disposed on the same plane.

### CROSS-REFERENCE TO RELATED APPLICATIONS

This application claims the benefit of and priority to Korean Patent Application No. 10-2024-0194091 filed on Dec. 23, 2024, in the Korean Intellectual Property Office, the entire contents of which are incorporated herein by reference for all purposes.

### BACKGROUND

### 1. Technical Field

The present disclosure relates to a display device, and particularly to, for example, without limitation, a display device which improves the delamination problem of a display panel while maintaining a flexibility characteristic.

### 2. Description of Related Art

As display devices which are used for a monitor of a computer, a television, or a cellular phone, there are an organic light emitting display device (OLED) which is a self-emitting device and a liquid crystal display device (LCD) which requires a separate light source.

An applicable range of the display device is diversified to personal digital assistants as well as monitors of computers and televisions and a display device with a large display area and a reduced volume and weight is being studied.

Further, recently, a display device in which a display element and a wiring line are formed on a flexible substrate, such as plastic which is a flexible material, is getting attention as a next generation display device.

The description of related art should not be considered prior art merely because it is mentioned in or associated with this section. The description of related art includes information that describes one or more aspects of the subject technology, and the description in this section does not limit the scope of the present disclosure.

### SUMMARY

An aspect of the present disclosure is to provide a display device in which a tensile stress applied to a display panel is reduced.

Another aspect of the present disclosure is to provide a display device in which delamination of the display panel is reduced.

Still another aspect of the present disclosure is to provide a display device in which a reinforcement layer is disposed below the display panel to change a neutral plane.

Aspects of the present disclosure are not limited to the above-mentioned aspects, and other aspects, which are not mentioned above, can be clearly understood by those skilled in the art from the following descriptions.

According to an aspect of the present disclosure, a display device includes a cover window; a flexible display panel disposed on a rear surface of the cover window; a metal plate disposed on a rear surface of the flexible display panel; and a plurality of first reinforcement layers which overlaps the cover window on the same layer as the metal plate and is formed of a different material from the metal plate.

According to another aspect of the present disclosure, a display device includes a display panel which includes a display element, a first inorganic encapsulation layer which covers the display element, an organic encapsulation layer on the first inorganic encapsulation layer, and a second inorganic encapsulation layer on the organic encapsulation layer; a back plate disposed on a rear surface of the display panel, and a plurality of first reinforcement layers disposed on a rear surface of the back plate, and the organic encapsulation layer includes a first part having a flat top surface and a second part which encloses the first part and has an inclined top surface, and the plurality of first reinforcement layers does not overlap the first part.

Other detailed matters of the example embodiments are included in the detailed description and the drawings.

According to one or more aspects of the present disclosure, a reinforcement layer is disposed below the display panel to reduce a tensile stress applied to the display panel.

According to one or more aspects of the present disclosure, a delamination problem of the display panel due to the bending is reduced.

According to one or more aspects of the present disclosure, a neutral plane of a center portion of the display unit and a neutral plane of an edge of the display unit are set to be different to reduce the delamination of the display unit while maintaining a bending characteristic of the display unit.

The effects according to one or more aspects of the present disclosure are not limited to the contents described above, and other effects are included in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a perspective view of a display device according to an example embodiment of the present disclosure;

FIG. 2 is a schematic exploded perspective view of a display unit of a display device according to an example embodiment of the present disclosure;

FIG. 3 is a schematic plan view of a display unit of a display device according to an example embodiment of the present disclosure;

FIG. 4 is a cross-sectional view taken along A-A′ of FIG. 3;

FIG. 5 is a cross-sectional view of a display unit of a display device according to another example embodiment of the present disclosure; and

FIG. 6 is a cross-sectional view of a display unit of a display device according to still another example embodiment of the present disclosure.

### DETAILED DESCRIPTION

Reference is now made in detail to embodiments of the present disclosure, examples of which may be illustrated in the accompanying drawings. In the following description, when a detailed description of well-known methods, functions, structures or configurations may unnecessarily obscure aspects of the present disclosure, the detailed description thereof may have been omitted for brevity. Further, repetitive descriptions may be omitted for brevity. The progression of processing steps and/or operations described is a non-limiting example.

The sequence of steps and/or operations is not limited to that set forth herein and may be changed to occur in an order that is different from an order described herein, with the exception of steps and/or operations necessarily occurring in a particular order. In one or more examples, two operations in succession may be performed substantially concurrently, or the two operations may be performed in a reverse order or in a different order depending on a function or operation involved.

Unless stated otherwise, like reference numerals may refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

Advantages and features of the present disclosure, and implementation methods thereof, are clarified through the embodiments described with reference to the accompanying drawings. The present disclosure may, however, be embodied in different forms and should not be construed as limited to the embodiments set forth herein. Rather, these embodiments are examples and are provided so that this disclosure may be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, steps, operations, and/or the like), one or more other elements may be added unless a term such as “only” or the like is used. The terms used in the present disclosure are merely used in order to describe particular example embodiments, and are not intended to limit the scope of the present disclosure. Any references to singular may include plural, and vice versa, unless expressly stated otherwise. In one or more examples, unless expressly stated otherwise, an element may be one or more elements; and an element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range may be caused by various factors (e.g., process factors, internal or external impact, noise, or the like). In interpreting a numerical value, the value is interpreted as including an error range unless explicitly stated otherwise.

When a positional relationship between two elements (e.g., layers, films, components, electrodes, structures, transistors, sections, members, parts, regions, areas, portions, and/or the like) are described using any of the terms such as “on,” “on a top of,” “upon,” “on top of,” “over,” “under,” “above,” “upper,” “at an upper portion,” “at a upper side,” “below,” “lower,” “at a lower portion,” “at a lower side,” “beneath,” “near,” “close to,” “adjacent to,” “beside,” “next to,” “at or on a side of,” and/or the like indicating a position or location, one or more other elements may be located between the two elements unless a more limiting term, such as “immediate(ly),” “direct(ly),” or “close(ly),” is used. For example, when an element and another element are described using any of the foregoing terms, this description should be construed as including a case in which the elements contact each other directly as well as a case in which one or more additional elements are disposed or interposed therebetween. Furthermore, the spatially relative terms such as the foregoing terms as well as other terms such as “front,” “rear,” “back,” “left,” “right,” “top,” “bottom,” “upper,” “lower,” “downward,” “upward,” “up,” “down,” “column,” “row,” “vertical,” “horizontal,” “diagonal,” and the like refer to an arbitrary frame of reference. For example, these terms may be used for an example understanding of a relative relationship between elements, including any correlation as shown in the drawings. However, embodiments of the disclosure are not limited thereby or thereto. The spatially relative terms are to be understood as terms including different orientations of the elements in use or in operation in addition to the orientation depicted in the drawings or described herein. For example, where a lower element or an element positioned under another element is overturned, then the element may be termed as an upper element or an element positioned above another element. Thus, for example, the term “under” or “beneath” may encompass, in meaning, the term “above” or “over.” An example term “below” or the like, can include all directions, including directions of “below,” “above” and diagonal directions. Likewise, an example term “above,” “on” or the like can include all directions, including directions of “above,” “on,” “below” and diagonal directions.

In describing a temporal relationship, when the temporal order is described as, for example, “after,” “following,” “subsequent,” “next,” “before,” “preceding,” “prior to,” or the like, a case that is not consecutive or not sequential may be included and thus one or more other events may occur therebetween, unless a more limiting term, such as “just,” “immediate(ly),” or “direct(ly),” is used.

It is understood that, although the terms “first,” “second,” “A,” “B,” “(a),” “(b),” and the like may be used herein to describe various elements (e.g., layers, films, components, electrodes, structures, transistors, sections, members, parts, regions, areas, portions, steps, operations, and/or the like), these elements should not be limited by these terms, for example, to any particular order, precedence, or number of elements. Further, these are not used to define the essence or basis of the elements. These terms are merely used to refer to one element separately from another. For example, a first element may denote a second element, and, similarly, a second element may denote a first element, without departing from the scope of the present disclosure. Furthermore, the first element, the second element, and the like may be arbitrarily named according to the convenience of those skilled in the art without departing from the scope of the present disclosure. For clarity, the functions or structures of these elements (e.g., the first element, the second element, and the like) are not limited by ordinal numbers or the names in front of the elements. Further, a first element may include one or more first elements. Similarly, a second element or the like may include one or more second elements or the like.

The expression that an element (e.g., layer, film, component, electrode, structure, transistor, section, member, part, region, area, portion, or the like) “is engaged” with another element may be understood, for example, as that the element may be either directly or indirectly engaged with the another element. The term “is engaged” or similar expressions may refer to a term such as “covers,” “surrounds,” “is in contact,” “overlaps,” “crosses,” “intersects,” “is connected,” “is coupled,” “is attached,” “is adhered,” “is combined,” “is linked,” “is provided,” “is disposed,” “interacts,” or the like. The engagement may involve one or more intervening elements disposed or interposed between the element and the another element, unless otherwise specified. Further, the element may be engaged at least partially or entirely (or completely) with the another element, unless otherwise specified. Further, the element may be included in at least one of two or more elements that are engaged with each other. Similarly, the another element may be included in at least one of two or more elements that are engaged with each other. When the element is engaged with the another element, at least a portion of the element may be engaged with at least a portion of the another element. The term “with another element” or similar expressions may be understood as “another element,” or “with, to, in, or on another element,” as appropriate by the context. Similarly, the term “with each other” may be understood as “each other,” or “with, to, or on each other,” as appropriate by the context.

The phrase “through” may be understood, for example, to be at least partially through or entirely through.

The terms such as a “line” or “direction” should not be interpreted only based on a geometrical relationship in which the respective lines or directions are parallel, perpendicular, diagonal, or slanted with respect to each other, and may be meant as lines or directions having wider directivities within the range within which the components of the present disclosure may operate functionally. For example, the terms “direction,” “first direction,” “second direction,” “bending direction,” “sliding direction,” and the like should not be interpreted only based on a geometrical relationship in which the respective directions are parallel, perpendicular, diagonal, or slanted with respect to each other, and may be meant as directions having wider directivities within the range within which the components of the present disclosure may operate functionally.

The term “at least one” should be understood as including any and all combinations of one or more of the associated listed items. For example, each of the phrases “at least one of a first item, a second item, or a third item” and “at least one of a first item, a second item, and a third item” may represent (i) a combination of items provided by two or more of the first item, the second item, and the third item or (ii) only one of the first item, the second item, or the third item. Further, at least one of a plurality of elements can represent (i) one element of the plurality of elements, (ii) some elements of the plurality of elements, or (iii) all elements of the plurality of elements. Further, “at least some,” “some,” “at least some portions,” “at least some parts,” “at least a portion,” “at least one or more portions,” “at least a part,” “at least one or more parts,” “at least some elements,” “one or more,” or the like of a plurality of elements can represent (i) one element of the plurality of elements, (ii) a portion (or a part) of the plurality of elements, (iii) one or more portions (or parts) of the plurality of elements, (iv) one or more elements of the plurality of elements, (v) multiple elements of the plurality of elements, or (vi) all of the plurality of elements. Moreover, “at least some,” “some,” “at least some portions,” “at least some parts,” “at least a portion,” “at least one or more portions,” “at least a part,” “at least one or more parts,” or the like of an element can represent (i) a portion (or a part) of the element, (ii) one or more portions (or parts) of the element, (iii) the element, or (iv) all portions of the element.

The expression of a first element, a second elements “and/or” a third element should be understood as any one of the first, second and third elements or as any or all combinations of the first, second and third elements. Similar interpretations apply to the use of “and/or” with two elements or with more than three elements. By way of example, A, B and/or C may refer to only A; only B; only C; any of A, B, and C (e.g., A, B, or C); some combination of A, B, and C (e.g., A and B; A and C; or B and C); or all of A, B, and C. Furthermore, an expression “A/B” may be understood as A and/or B. For example, an expression “A/B” may refer to only A; only B; A or B; or A and B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two. Furthermore, when an element is referred to as being “between” at least two elements, the element may be the only element between the at least two elements, or one or more intervening elements may also be present.

In one or more aspects, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

In one or more aspects, the phrases “one or more among” and “one or more of” may be used interchangeably simply for convenience unless stated otherwise.

The term “or” means “inclusive or” rather than “exclusive or.” That is, unless otherwise stated or clear from the context, the expression that “x uses a or b” means any one of natural inclusive permutations. For example, “a or b” may mean “a,” “b,” or “a and b.” For example, “a, b or c” may mean “a,” “b,” “c,” “a and b,” “b and c,” “a and c,” or “a, b and c.”

A phrase “substantially the same” or “nearly the same” may indicate a degree of being considered as being equivalent to each other taking into account minute differences due to errors in the manufacturing process.

In one or more examples, when an element extends from a first area to a second area, the element may be disposed in the first area and the second area.

Features of various embodiments of the present disclosure may be partially or entirely coupled to or combined with each other, may be technically associated with each other, and may be variously operated, linked or driven together in various ways. Embodiments of the present disclosure may be implemented or carried out independently of each other or may be implemented or carried out together in a co-dependent or related relationship. In one or more aspects, the components of each apparatus and device according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

The terms used herein have been selected as being general in the related technical field; however, there may be other terms depending on the development and/or change of technology, convention, preference of technicians, and so on. Therefore, the terms used herein should not be understood as limiting technical ideas, but should be understood as examples of the terms for describing example embodiments.

Further, in a specific case, a term may be arbitrarily selected by an applicant, and in this case, the detailed meaning thereof is described herein. Therefore, the terms used herein should be understood based on not only the name of the terms, but also the meaning of the terms and the content hereof.

In the following description, various example embodiments of the present disclosure are described in more detail with reference to the accompanying drawings. With respect to reference numerals to elements of each of the drawings, the same or similar elements may be illustrated in other drawings, and like reference numerals may refer to like or similar elements unless stated otherwise. The same or similar elements may be denoted by the same reference numerals even if they are depicted in different drawings. Repetitive descriptions of the same or similar elements may be omitted for brevity, and the descriptions provided for elements in one or more figures may also apply to elements in other figures that use the same or similar reference numerals unless stated otherwise. In addition, for the convenience of description, a scale, dimension, size, and thickness of each of the elements illustrated in the accompanying drawings may be different from an actual scale, dimension, size, and thickness, and thus, embodiments of the present disclosure are not limited to a scale, dimension, size, and thickness illustrated in the drawings.

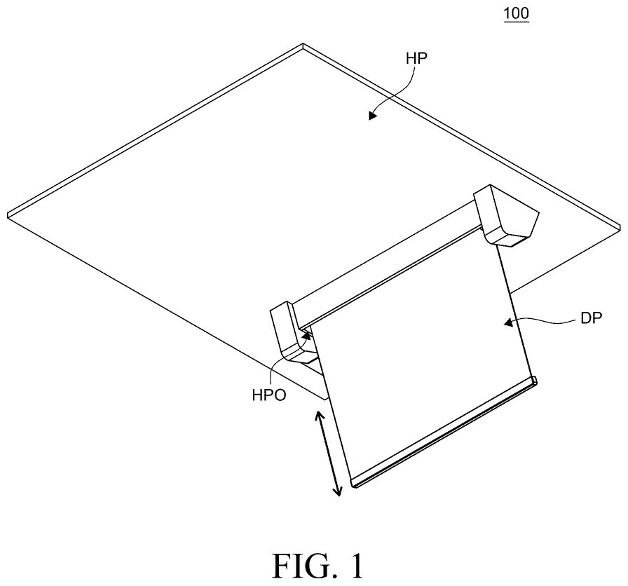

FIG. 1 is a perspective view of a display device according to an example embodiment of the present disclosure. Referring to FIG. 1, a display device 100 according to an example embodiment of the present disclosure includes a display unit DP and a housing unit HP.

The housing unit HP is a case in which the display unit DP is accommodated.

The housing unit HP has an opening HPO through which the display unit DP moves to the inside and the outside of the housing unit HP.

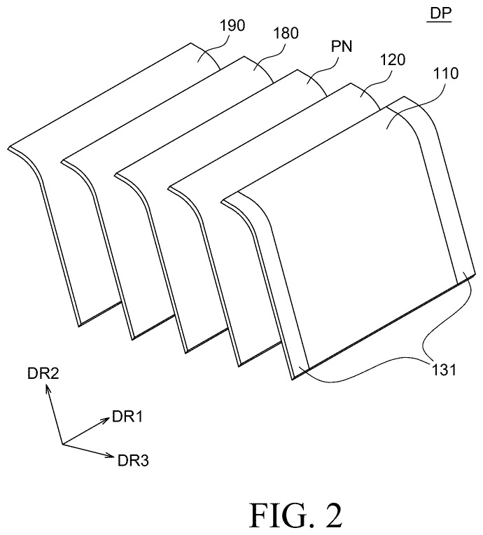

The display unit DP is a configuration for displaying images to a user and for example, a display element and a circuit, a wiring line, and a component for driving the display element may be disposed. In one or more aspects, the display unit DP of the display device 100 according to the example embodiment of the present disclosure has a flexibility. The display unit DP will be described below in more detail with reference to FIGS. 2 to 4.

The display unit DP is configured to be slidable and/or bendable. For example, as a guide member (not illustrated) moves, the display unit DP of the display device 100 slides and/or is bent to the outside of a housing unit HP or is accommodated in the housing unit HP. In one or more aspects, a part of the display unit DP disposed in the housing unit HP may form a slope together with the other part of the display unit DP disposed at the outside of the housing unit HP.

In the meantime, even though in FIG. 1, it has been described that the display device 100 is configured by the display unit DP and the housing unit HP, the display device 100 according to the example embodiment of the present disclosure may be configured only by the display unit DP. For example, the housing unit HP of FIG. 1 may be an independent configuration from the display device 100 according to the example embodiment of the present disclosure, but is not limited thereto.

Hereinafter, the display unit DP of the display device 100 according to the example embodiment of the present disclosure will be described in detail.

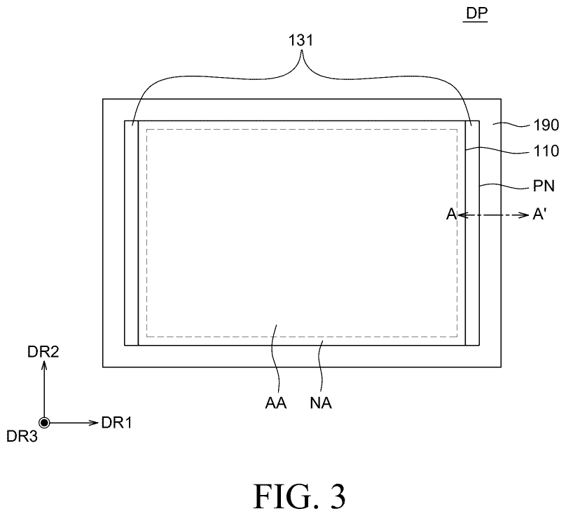

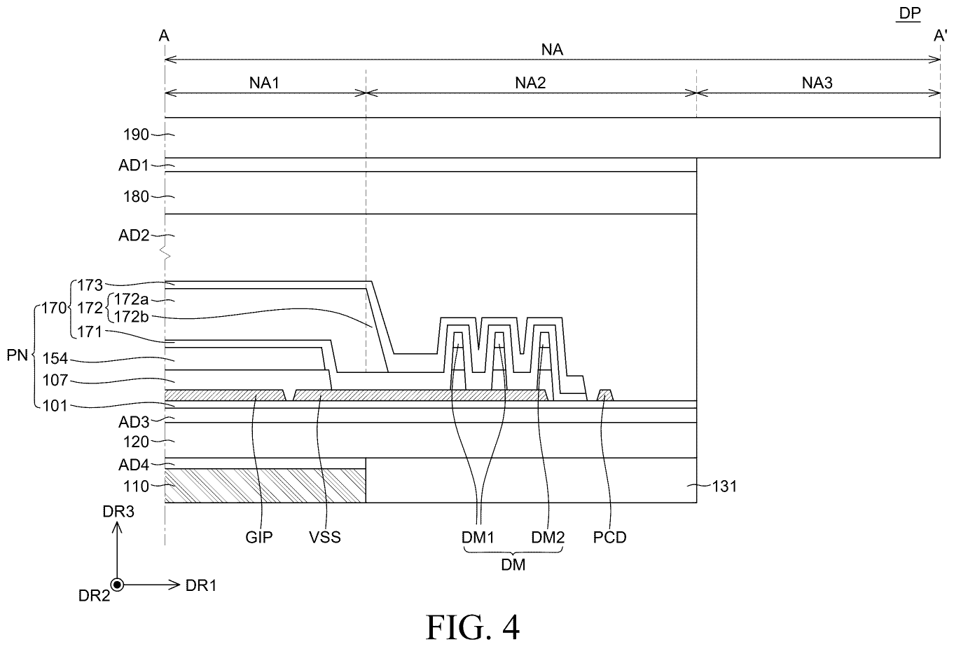

FIG. 2 is a schematic exploded perspective view of a display unit of a display device according to an example embodiment of the present disclosure. FIG. 3 is a schematic plan view of a display unit of a display device according to an example embodiment of the present disclosure. FIG. 4 is a cross-sectional view taken along A-A′ of FIG. 3. FIG. 4 is a cross-sectional view of a non-active area NA of a display unit DP of a display device 100 according to an example embodiment of the present disclosure.

Referring to FIGS. 3 and 4, the display unit DP includes an active area AA and a non-active area NA.

The active area AA is an area where images are displayed in the display unit DP. In the active area AA, a plurality of sub pixels which configures a plurality of pixels and a driving circuit for driving the plurality of sub pixels may be disposed. The plurality of sub pixels is minimum units which configure the active area AA and a display element may be disposed in each of the plurality of sub pixels. For example, an organic light emitting diode which includes an anode, an organic emission layer, and a cathode may be disposed in each of the plurality of sub pixels, but it is not limited thereto. Further, a driving circuit for driving the plurality of sub pixels may include a driving element and a wiring line. For example, the driving circuit may be configured by a thin film transistor, a storage capacitor, a gate line, and a data line, but is not limited thereto.

The non-active area NA is an area where no image is displayed. In the non-active area NA, various wiring lines and circuits for driving the display element of the active area AA are disposed. For example, in the non-active area NA, a link line which transmits signals to the plurality of sub pixels and driving circuits of the active area AA or a driving IC such as a gate driver IC or a data driver IC may be disposed, but the non-active area is not limited thereto.

Referring to FIG. 4, the non-active area NA includes a first non-active area NA1, a second non-active area NA2, and a third non-active area NA3.

The first non-active area NA1 extends from the active area AA. In the first non-active area NA1, a gate driver GIP of the display panel PN for driving the display element of the active area AA is disposed.

The second non-active NA2 extends from the first non-active area NA1. In the second non-active area NA2, a part of an encapsulation layer 170 of the display panel PN extending from the active area AA and the first non-active area NA1 may be disposed. Further, in the second non-active area NA2, a part of the display unit DP disposed at the outside of the encapsulation layer 170 may be disposed.

The third non-active area NA3 is an area extending from the second non-active area NA2 and may be an outermost peripheral area of the display unit DP. In the third non-active area NA3, a cover window 190 extending from the active area AA, the first non-active area NA1, and the second non-active area NA2 is disposed, but a metal plate 110, a back plate 120, a display panel PN, and a polarization plate 180 may be not disposed.

Referring to FIGS. 2 to 4, the display unit DP may include a metal plate 110, a back plate 120, a display panel PN, a polarization plate 180, a cover window 190, a first adhesive layer AD1, a second adhesive layer AD2, a third adhesive layer AD3, a fourth adhesive layer AD4, and a plurality of first reinforcement layers 131. Hereinafter, for the convenience of description, as illustrated in FIG. 4, the display unit DP will be described as having a metal plate 110 disposed on the lower side and a cover window 190 disposed on the upper side.

Referring to FIG. 2, the display unit DP is bent in one direction. For example, the display unit DP slides and/or is bent to a second direction DR2. That is, the metal plate 110, the back plate 120, the display panel PN, the polarization plate 180, the cover window 190, and the plurality of first reinforcement layers 131 which configure the display unit DP are bent to the second direction DR2. In one or more aspects, as illustrated in FIG. 2, the display unit DP is bent to a direction which is opposite to the cover window 190.

The configuration of the display unit DP that slides and/or is bent to a second direction DR2 or that is bent to a direction which is opposite to the cover window 190 may be described as follows in various non-limiting examples. Referring to FIG. 2, in an example, a bent portion of the display unit DP may extend along a third direction DR3, or along a negative third direction DR3.

Referring to FIGS. 3 and 4, the cover window 190 is disposed so as to cover the display panel PN. For example, the cover window 190 is disposed so as to have a size larger than a size of the display panel PN to protect the display panel PN from the shocks, moisture, and heat from the outside.

The cover window 190 is configured by a material having a large modulus value, to reduce a crack due to the external shocks. For example, the cover window 190 may be formed of glass. In one or more aspects, in consideration of a bending characteristic of the display panel DP, the cover window 190 is disposed with a small thickness.

In the meantime, a black matrix layer (not illustrated) is disposed on a rear surface of the cover window 190.

The black matrix layer is disposed so as to correspond to the non-active area NA of the display unit DP. The black matrix layer includes a material which absorbs light, for example, carbon black or a black resin. Accordingly, components, such as wiring lines disposed in the non-active area NA of the display unit DP are not visible from the outside. Further, the black matrix layer serves to suppress light leakage which may occur in a side portion of the display unit DP.

Referring to FIG. 4, the first adhesive layer AD1 is disposed between the cover window 190 and the polarization plate 180. The first adhesive layer AD1 fixes the polarization plate 180 and the cover window 190. The first adhesive layer AD1 may be configured by an optically clear adhesive (OCA) which minimizes foreign particles or bubbles generated between the polarization plate 180 and the cover window 190, but is not limited thereto.

The polarization plate 180 is disposed on a rear surface of the first adhesive layer AD1. The polarization plate 180 selectively transmits light to reduce the reflection of external light which is incident to the display panel PN. Specifically, the display panel PN includes various metal materials applied to a semiconductor element, a wiring line, and a display element. Therefore, the external light incident onto the display panel PN may be reflected from the metal material so that the visibility of the display unit DP may be reduced due to the reflection of the external light. Therefore, the polarization plate 180 suppresses reflection of the external light, thereby increasing outdoor visibility of the display unit DP. However, the polarization plate 180 may be omitted depending on an implementation example of the display unit DP.

The second adhesive layer AD2 is disposed between the polarization plate 180 and the display panel PN. The second adhesive layer AD2 fixes the polarization plate 180 and the display panel PN. The second adhesive layer AD2 may be configured by an optically clear adhesive (OCA) which minimizes foreign particles or bubbles generated between the polarization plate 180 and the display panel PN, but is not limited thereto.

The display panel PN is disposed on rear surfaces of the polarization plate 180 and the second adhesive layer AD2.

The display panel PN is a panel for displaying images to a user. In the display panel PN, a display element which displays images, a driving element which drives the display element, and wiring lines which transmit various signals to the display element and the driving element are disposed.

The display element may be defined in different manners depending on the type of the display panel PN. For example, when the display panel PN is an organic light emitting display panel, the display element may be an organic light emitting diode which includes an anode, an organic emission layer, and a cathode. For example, when the display panel PN is a liquid crystal display panel, the display element may be a liquid crystal display element. Hereinafter, even though the display panel PN is assumed as an organic light emitting display panel, the display panel PN is not limited to the organic light emitting display panel. Further, the display panel PN of the display device 100 according to the example embodiment of the present disclosure may be implemented as a flexible display panel to slide and/or be bent.

Referring to FIG. 4, in the non-active area NA, a substrate 101, a planarization layer 107, a bank 154, an encapsulation layer 170, a gate driver GIP, a low potential power line VSS, a crack detection line PCD, and a plurality of dams DM of the display panel PN are disposed.

The substrate 101 of the display panel PN is disposed on the back plate 120. The substrate 101 is disposed in the active area AA, the first non-active area NA1, and the second non-active area NA2 to support configurations of the display panel PN disposed above the substrate 101. The substrate 10 may be formed of an insulating material having a flexibility, for example, may be formed of an insulating material, such as polyimide, polyethersulfone, polyethylene terephthalate, and polycarbonate.

Even though it is not illustrated in the drawing, an insulating layer may be disposed between the substrate 101 and the gate driver GIP. The insulating layer may be disposed in the active area AA, the first non-active area NA1, and the second non-active area NA2. The insulating layer reduces permeation of moisture or impurities to a configuration above the substrate 101, through the substrate 101. The insulating layer may be formed of a material, such as amorphous silicon (a-Si), silicon nitride (SiNx), and silicon oxide (SiOx), but is also formed of an insulating organic material.

The gate driver GIP, the low potential power line VSS, and the crack detection line PCD are disposed on the substrate 101.

The gate driver GIP is disposed on the substrate 101. For example, the gate driver GIP may be disposed in the first non-active area NA1. The gate driver GIP includes a transistor and/or a capacitor. The gate driver GIP supplies a gate driving voltage which is supplied through a gate pad to the active area AA. The gate driver GIP may be formed of the same material as a plurality of electrodes which configures a plurality of transistors disposed in the active area AA, for example, a source electrode or a drain electrode, but is not limited thereto.

In the meantime, in FIG. 4, for the convenience of illustration, it is illustrated that the gate driver GIP is formed by one layer, but the gate driver GIP may be formed by a plurality of layers and/or a plurality of electrodes. For example, the gate driver GIP includes a plurality of layers and/or a plurality of electrodes which configures various components, such as a plurality of transistors or capacitors.

The low potential power line VSS is disposed on the substrate 101. The low potential power line VSS is disposed at the outside of the gate driver GIP. For example, the low potential power link line VSS may be disposed in the first non-active area NA1 and the second non-active area NA2. The low potential power line VSS is disposed so as to enclose an outer peripheral area and is disposed so as to overlap an organic encapsulation layer 172 in the outer peripheral area of the substrate 101. The low potential power line VSS may be formed of the same material as a plurality of electrodes which configures a plurality of transistors disposed in the active area AA, for example, a source electrode or a drain electrode, but is not limited thereto.

The crack detection line PCD is disposed at the outside of the gate driver GIP on the substrate 101. For example, the crack detection line PCD is disposed so as to enclose a dam DM in the second non-active area NA2 at the outside of the dam DM and is disposed so as to enclose the low potential power line VSS. The crack detection line PCD may be formed of the same material as a plurality of electrodes which configures a plurality of transistors disposed in the active area AA, for example, a source electrode or a drain electrode, but is not limited thereto.

The planarization layer 107, the bank 154, the plurality of dams DM, and the encapsulation layer 170 are disposed on the gate driver GIP and the low potential power line VSS.

The planarization layer 107 is an insulating layer which planarizes an upper portion of the substrate 101. The planarization layer 107 may be formed of an organic material, and for example, may be configured by a single layer or a double layer of polyimide or photo acryl, but is not limited thereto. The planarization layer 107 extends from the active area AA to the first non-active area NA1 and covers between the gate driver GIP and the low potential power line VSS.

The bank 154 is disposed on the planarization layer 107. The bank 154 is an insulating layer disposed between the plurality of sub pixels to divide the plurality of sub pixels disposed in the active area AA. The bank 154 may be an organic insulating material. For example, the bank 154 may be formed of polyimide, acryl, or benzocyclobutene (BCB) resin, but it is not limited thereto.

The plurality of dams DM is disposed on the substrate 101 and the low potential power line VSS. The plurality of dams DM is disposed so as to overlap the low potential power line VSS. The plurality of dams DM suppresses overflow of the organic encapsulation layer 172. For example, the plurality of dams DM is disposed so as to enclose an end of the organic encapsulation layer 172 in the second non-active area NA2. As illustrated in FIG. 4, the plurality of dams DM is formed of a plurality of layers. The plurality of dams DM is formed of the same material as a material disposed in the active area AA, and for example, is formed of the same material as a spacer, the bank 154, and the planarization layer 107, but is not limited thereto.

The plurality of dams DM may include a plurality of first dam DM1 and a second dam DM2.

The plurality of first dams DM1 is disposed on the low potential power line VSS and is disposed to be adjacent to the active area AA more than the second dam DM2.

The second dam DM2 is disposed to be adjacent to the third non-active area NA3 more than the plurality of first dams DM1. In one or more aspects, the second dam DM2 is disposed so as to cover an end of the low potential power line VSS. For example, a part of the second dam DM2 is in contact with a top surface of the low potential power line VSS and the other part of the second dam DM2 is in contact with the substrate 101 at the outside of the low potential power line VSS, but is not limited thereto.

The encapsulation layer 170 is disposed on the bank 154, the low potential power line VSS, and the dam DM. The encapsulation layer 170 protects the display element disposed in the display device 100 from moisture permeating from the outside. The encapsulation layer 170 may include a first inorganic encapsulation layer 171, an organic encapsulation layer 172, and a second inorganic encapsulation layer 173.

The first inorganic encapsulation layer 171 may extend from the active area AA to the first non-active area NA1 and the second non-active area NA2. The first inorganic encapsulation layer 171 suppresses the permeation of the moisture or oxygen. The first inorganic encapsulation layer 171 may be formed of an inorganic material, such as silicon oxide (SiOx), silicon nitride (SiNx), silicon oxy nitride (SiNxOy), or aluminum oxide (AlyOz), but is not limited thereto.

The organic encapsulation layer 172 is disposed on the first inorganic encapsulation layer 171 and may extend from the active area AA to the first non-active area NA1 and the second non-active area NA2. For example, an end of the organic encapsulation layer 172 is disposed at the inside of the dam DM.

The organic encapsulation layer 172 is disposed on the first inorganic encapsulation layer 171 to planarize an upper surface of the first inorganic encapsulation layer 171 and cover foreign materials or particles which may occur during a manufacturing process. The organic encapsulation layer 172 may be formed of an organic material, such as silicon oxy carbon (SiOxCz), acryl, or epoxy resin, but is not limited thereto.

The organic encapsulation layer 172 includes a first part 172a having a flat top surface and a second part 172b which encloses the first part 172a and has an inclined top surface.

The first part 172a is disposed in the active area AA and the first non-active area NA1 and covers an end of the planarization layer 107 and an end of the bank 154 disposed in the first non-active area NA1.

The second part 172b is disposed in the second non-active area NA2 and covers a part of the top surface of the low potential power line VSS at the outside of the planarization layer 107 and the bank 154.

The second inorganic encapsulation layer 173 is disposed on the organic encapsulation layer 172 and may extend from the active area AA to the first non-active area NA1 and the second non-active area NA2. The second inorganic encapsulation layer 173 is in contact with the first inorganic encapsulation layer 171 at the outside of the end of the organic encapsulation layer 172. The second inorganic encapsulation layer 173 suppresses permeation of moisture and oxygen, like the first inorganic encapsulation layer 171. In one or more aspects, the second inorganic encapsulation layer 173 and the first inorganic encapsulation layer 171 may be formed to seal the organic encapsulation layer 172. Accordingly, the moisture or oxygen permeating the display element disposed in the display device 100 may be effectively reduced by the second inorganic encapsulation layer 173. The second inorganic encapsulation layer 173 may be formed of an inorganic material, such as silicon oxide (SiOx), silicon nitride (SiNx), silicon oxy nitride (SiNxOy), or aluminum oxide (AlyOz), but is not limited thereto.

Referring to FIG. 4, the second adhesive layer AD2 is filled in a step above the encapsulation layer 170. Therefore, the encapsulation layer 170 and the display element disposed below the encapsulation layer 170 are sealed by the second adhesive layer AD2. For example, the second adhesive layer AD2 is formed of a material which is easily deformed when a stress or a pressure is applied, to cover a surface of the encapsulation layer 170. Therefore, the second adhesive layer AD2 suppresses moisture and oxygen from permeating the plurality of display element disposed below the encapsulation layer 170.

For example, the second adhesive layer AD2 is disposed on the flat top surface of the first part 172a in the active area AA and the first non-active area NA1. Further, the second adhesive layer AD2 is disposed on the inclined top surface of the second part 172b in the second non-active area NA2 and covers the plurality of dams DM and the crack detection line PCD disposed at the outside of the second part 172b. Therefore, a thickness of the second adhesive layer AD2 in the second non-active area NA2 is larger than a thickness of the second adhesive layer AD2 in the first non-active area NA1.

Referring to FIG. 4, the third adhesive layer AD3 is disposed between the substrate 101 of the display panel PN and the back plate 120. The third adhesive layer AD3 may fix the display panel PN and the back plate 120. The third adhesive layer AD3 may be formed by an optically clear adhesive layer (OCA) which minimizes foreign particles or bubbles generated between the display panel PN and the back plate 120, but is not limited thereto.

The back plate 120 is disposed on the rear surfaces of the display panel PN and the third adhesive layer AD3. The back plate 120 not only supports the display panel PN, but also protects the display panel PN from external moisture, heat, and shocks. The back plate 120 is formed of polyimide or polyethylene terephthalate, but is not limited thereto.

The fourth adhesive layer AD4 is disposed between the back plate 120 and the metal plate 110. The fourth adhesive layer AD4 may bond the back plate 120 and the metal plate 110. The fourth adhesive layer AD4 may be formed of a pressure sensitive adhesive (PSA) which minimizes generation of foreign materials or bubbles between the back plate 120 and the metal plate 110, but is not limited thereto.

Referring to FIGS. 2 to 4, the metal plate 110 is disposed on rear surfaces of the back plate 120 and the fourth adhesive layer AD4.

A size of the metal plate 110 may be smaller than a size of the display panel PN. For example, referring to FIG. 3, a width of the metal plate 110 is smaller than a width of the display panel PN in the first direction DR1. Further, referring to FIG. 4, the display panel PN extends from the active area AA to be disposed in the first non-active area NA1 and the second non-active area NA2, but the metal plate 110 extends from the active area AA to be disposed in the first non-active area NA1, but is not disposed in the second non-active area NA2.

The metal plate 110 supports the display panel PN and protects the display unit DP from the outside. The metal plate 110 is disposed on the rear surface of the display panel PN so that it is referred to as a metal plate, but it is not limited thereto.

The metal plate 110 may include a malleable material so that the display panel PN is not deformed even though the sliding and/or bending operation is repeated. The metal plate 110 is formed of a metal material, such as steel use stainless (SUS) or invar or a plastic material, but is not limited thereto. In the meantime, the metal plate 110 includes a plurality of openings so as to be flexibly deformed by the stress which occurs in the bending direction. Therefore, the metal plate 110 minimizes a stress applied to the display panel PN, while minimizing the slip phenomenon of the display panel PN.

A plurality of first reinforcement layers 131 is disposed on the rear surface of the back plate 120. Referring to FIG. 4, the plurality of first reinforcement layers 131 is disposed on the same layer as the metal plate 110. For example, the rear surfaces of the plurality of first reinforcement layers 131 are disposed on the same plane as the rear surface of the metal plate 110.

The plurality of first reinforcement layers 131 may be disposed in the second non-active area NA2 disposed at the outside of the metal plate 110. Therefore, the plurality of first reinforcement layers 131 overlaps the cover window 190, the polarization plate 180, the display panel PN, and the back plate 120 in the second non-active area NA2. In contrast, the plurality of first reinforcement layers 131 is disposed so as not to overlap the first part 172a disposed in the active area AA and the first non-active area NA1.

The plurality of first reinforcement layers 131 is disposed along a sliding direction and/or a bending direction of the display unit DP. For example, when the display unit DP slides and/or is bent in the second direction DR2, as illustrated in FIG. 3, the plurality of first reinforcement layers 131 extends along the second direction DR2. In one or more aspects, the plurality of first reinforcement layers 131 is disposed to be spaced apart from each other with the metal plate 110 therebetween in the first direction DR1. Further, the plurality of first reinforcement layers 131 is in contact with an edge of the metal plate 110 extending in the second direction DR2. However, the present disclosure is not limited thereto and the plurality of first reinforcement layers 131 extends in the first direction DR1 and the second direction DR2 to enclose all the edges of the metal plate 110.

Referring to FIG. 4, edges of the plurality of first reinforcement layers 131 are disposed on the same plane as an edge of the polarization plate 180, an edge of the display panel PN, and an edge of the back plate 120. Accordingly, the edge of the polarization plate 180, the edge of the display panel PN, and the edge of the back plate 120 are exposed from the plurality of first reinforcement layers 131.

The plurality of first reinforcement layers 131 is formed of a material different from that of the metal plate 110 and the back plate 120. For example, a modulus of the plurality of first reinforcement layers 131 is equal to or larger than a modulus of the back plate 120. For example, the plurality of first reinforcement layers 131 is formed of a resin material or may be formed of the same material as the back plate 120, such as polyimide or polyethylene terephthalate, but is not limited thereto.

When the display unit is bent in a direction which is opposite to the cover window, a compressive stress is applied to the cover window and a tensile stress is applied to the back plate. Accordingly, when a neutral plane of the display unit is located between the display panel and the cover window, a compressive stress is applied to a configuration above the display panel, for example, a cover window and a polarization plate. In contrast, a tensile stress is applied to the display panel and a configuration below the display panel, for example, the display panel, the metal plate, and the back plate. However, the configuration disposed in the area on which the tensile stress acts may be more vulnerable to the external force, than the configuration disposed in the area on which the compressive stress acts. Accordingly, when the display unit is bent in a direction which is opposite to the cover window, the tensile stress is applied to the display panel so that delamination may occur between layers which configure the display panel. Accordingly, the delamination caused in the edge of the display panel propagates to a center portion of the display panel. Specifically, when a radius of bending curvature of the display panel is reduced, the interlayer delamination of the display panel may be deepened.

Therefore, in the display device 100 according to the example embodiment of the present disclosure, the plurality of first reinforcement layers 131 is disposed below the display panel PN to adjust a neutral plane of the display unit DP. For example, the plurality of first reinforcement layers 131 is disposed below the display panel PN and the back plate 120 and is formed of a material having a modulus which is equal to or larger than a modulus of the back plate 120. Accordingly, the plurality of first reinforcement layers 131 suppresses the neutral plane of the display unit DP from being located to be adjacent to the cover window 190. Therefore, when the display unit DP is bent to the direction which is opposite to the cover window 190, the plurality of first reinforcement layers 131 suppresses the tensile stress from being applied to the display panel PN. Further, when the tensile stress is applied to the display panel PN, a tensile stress which does not cause the interlayer delamination of the display panel PN may be applied. Accordingly, in the display device 100 according to the example embodiment of the present disclosure, the plurality of first reinforcement layers 131 is disposed in the display unit DP to suppress the interlayer delamination of the display panel PN and improve the reliability of the display device 100.

Further, in the display device 100 according to the example embodiment of the present disclosure, the first reinforcement layer 131 is disposed so as to correspond to the edge of the display panel PN. Therefore, the delamination problem of the display unit DP may be reduced while maintaining the bending characteristic of the display panel PN. For example, when a reinforcement material having a large modulus is disposed so as to correspond to a front surface of the display panel, a position of the neutral plane is changed on the front surface of the display unit. In this case, there may be a problem in the bending characteristic of the display unit due to the increased rigidity of the display unit and another problem, other than the delamination problem, may occur in the display unit. Accordingly, in the display device 100 according to the example embodiment of the present disclosure, the plurality of first reinforcement layers 131 is disposed so as to correspond to the edge of the display panel PN. For example, in the second non-active area NA2 of the display unit DP, the second adhesive layer AD2 which is formed of a material having a low modulus is disposed with a large thickness. Therefore, in the second non-active area NA2 of the display unit DP, the neutral plane is located to be adjacent to the cover window 190 more than the active area AA and the first non-active area NA1 of the display unit DP. Therefore, in the display device 200 according to the example embodiment of the present disclosure, the plurality of first reinforcement layers 131 is disposed in the second non-active area NA2 in which the second adhesive layer AD2 is disposed with a large thickness. Accordingly, the plurality of first reinforcement layers 131 suppresses a neutral plane change which rapidly changes in the second non-active area NA2 to minimize the delamination problem of the display panel PN.

Further, in the display device 100 according to the example embodiment of the present disclosure, the modulus of the display panel PN itself is not adjusted, but the modulus of the display panel PN is adjusted by placing the plurality of first reinforcement layers 131. Therefore, the neutral plane of the display unit DP is changed without changing a design of the display panel PN. Accordingly, the problem of the display panel PN which may occur by the design change of the display panel PN is suppressed and the problems, such as increase of manufacturing cost of the display panel PN and increase of repulsive force of the display panel PN, may be suppressed.

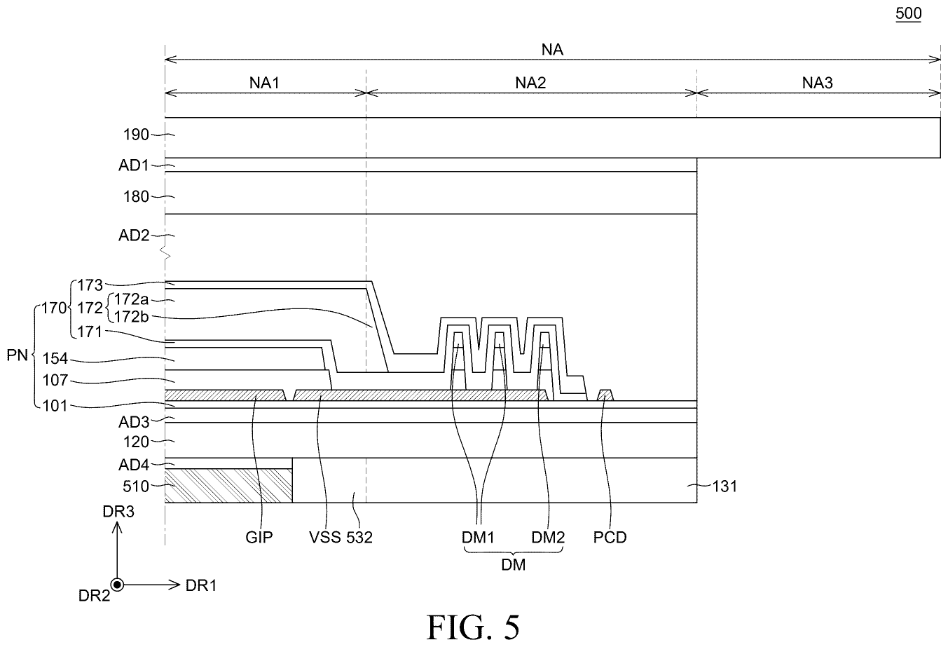

FIG. 5 is a cross-sectional view of a display unit of a display device according to another example embodiment of the present disclosure. A display device 500 of FIG. 5 is different from the display device 100 of FIGS. 1 to 4 in that a fourth adhesive layer AD4 and a metal plate 510 are different and a plurality of second reinforcement layers 532 is added, but the other configuration is substantially the same so that a redundant description will be omitted. Therefore, the descriptions provided for elements in one or more figures may also apply to elements in other figures that use the same or similar reference numerals unless stated otherwise.

Referring to FIG. 5, a metal plate 510 and a fourth adhesive layer AD4 are disposed on a rear surface of the back plate 120. The metal plate 510 and the fourth adhesive layer AD4 may extend from the active area AA to be disposed in the first non-active area NA1. In one or more aspects, the metal plate 510 and the fourth adhesive layer AD4 are disposed in the first non-active area NA1 so as to expose a part of the rear surface of the back plate 120. For example, in the first direction DR1, an end of the metal plate 510 and an end of the fourth adhesive layer AD4 are disposed to be adjacent to the active area AA more than an end of the first part 172a.

A plurality of second reinforcement layers 532 is disposed on the rear surface of the back plate 120. The plurality of second reinforcement layers 532 is disposed on the same layer as the metal plate 510. For example, the rear surfaces of the plurality of second reinforcement layers 532 are disposed on the same plane as the rear surface of the metal plate 510.

The plurality of second reinforcement layers 532 may be disposed in the first non-active area NA1 disposed at the outside of the metal plate 510. In one or more aspects, the plurality of second reinforcement layers 532 covers the rear surface of the back plate 120 exposed between the plurality of first reinforcement layers 131. Further, the plurality of second reinforcement layers 532 overlaps the cover window 190, the polarization plate 180, the display panel PN, and the back plate 120 in the first non-active area NA1 and overlaps a part of the first part 172a disposed in the first non-active area NA1.

The plurality of second reinforcement layers 532 is disposed along a sliding direction and/or a bending direction of the display unit DP. For example, when the display unit DP slides and/or is bent in the second direction DR2, the plurality of second reinforcement layers 532 extends along the second direction DR2. In the meantime, the plurality of second reinforcement layers 532 is not limited thereto, but may extend along the first direction DR1 to enclose the active area AA.

The plurality of second reinforcement layers 532 is disposed between the metal plate 510 and the plurality of first reinforcement layers 131 to be in contact with the edge of the metal plate 510 and the edges of the plurality of first reinforcement layers 131.

The plurality of second reinforcement layers 532 is formed of a material different from that of the metal plate 510 and the back plate 120. For example, the plurality of second reinforcement layers 532 is formed of the same material as the plurality of first reinforcement layers 131.

In the display device 500 according to another example embodiment of the present disclosure, the plurality of first reinforcement layers 131 which is disposed below the display panel PN and the back plate 120 and has a modulus equal to or larger than that of the back plate 120 is disposed to apply a level of stress which does not cause the interlayer delamination to the display panel PN. Accordingly, in the display device 500 according to another example embodiment of the present disclosure, the interlayer delamination of the display panel PN is suppressed and the reliability of the display device 500 is improved.

Further, in the display device 500 according to another example embodiment of the present disclosure, the first reinforcement layer 131 is disposed in the second non-active area NA2 in which the second adhesive layer AD2 is disposed with a large thickness. The neutral plane which is rapidly changed in the second non-active area NA2 is suppressed and the delamination problem of the display panel PN is minimized.

Further, in the display device 500 according to another example embodiment of the present disclosure, the plurality of first reinforcement layers 131 is disposed without changing the design of the display panel PN to adjust the modulus of the display panel PN so that the problems, such as increase of the manufacturing cost of the display panel PN and increase of the repulsive force of the display panel PN, may be suppressed.

Further, in the display device 500 according to another example embodiment of the present disclosure, the plurality of second reinforcement layers 532 which is formed of the same material as the plurality of first reinforcement layers 131 is disposed in the first non-active area NA1. Therefore, a stress which does not cause the interlayer delamination may be applied to the display panel PN. For example, the plurality of second reinforcement layers 532 is disposed below the display panel PN and the back plate 120 and is formed of a material having a modulus which is equal to or larger than a modulus of the back plate 120. Accordingly, the plurality of second reinforcement layers 532 suppresses the neutral plane of the display unit DP from being located to be adjacent to the cover window 190 in the first non-active area NA1. Therefore, when the display unit DP is bent to the direction which is opposite to the cover window 190, the plurality of second reinforcement layers 532 suppresses the tensile stress from being applied to the display panel PN. Further, when the tensile stress is applied to the display panel PN, a tensile stress which does not cause the interlayer delamination of the display panel PN may be applied. Accordingly, the plurality of second reinforcement layers 532 suppresses a neutral plane change which rapidly changes in the first non-active area NA2 to minimize the delamination problem of the display panel PN.

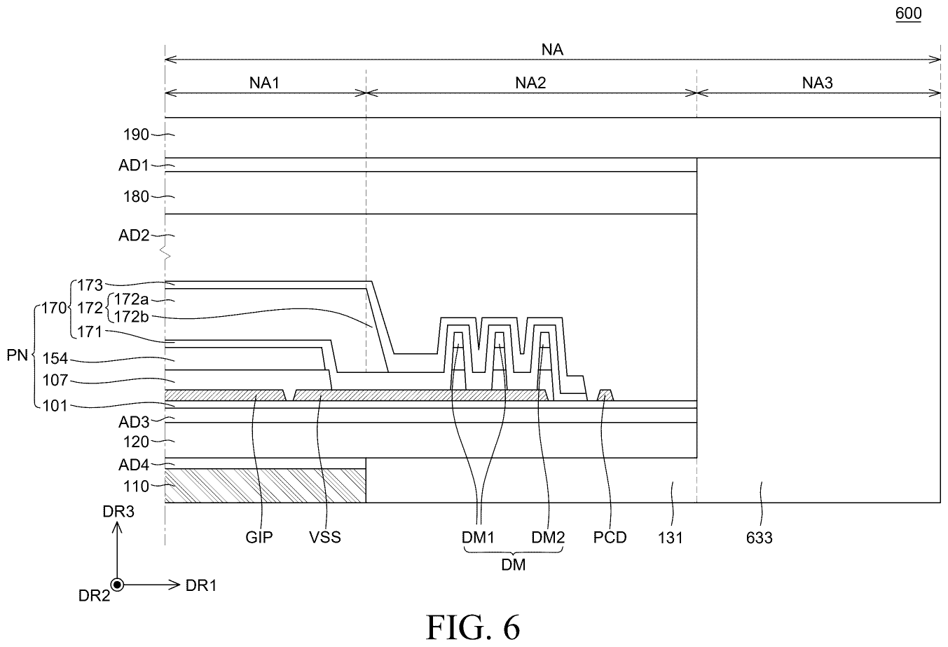

FIG. 6 is a cross-sectional view of a display unit of a display device according to still another example embodiment of the present disclosure. The only difference between a display device 600 of FIG. 6 and the display device 100 of FIGS. 1 to 4 is that a plurality of third reinforcement layers 633 is added, but the other configuration is substantially the same, so that a redundant description will be omitted. Therefore, the descriptions provided for elements in one or more figures may also apply to elements in other figures that use the same or similar reference numerals unless stated otherwise.

Referring to FIG. 6, a plurality of third reinforcement layers 633 is disposed in a third non-active area NA3. The plurality of third reinforcement layers 633 is disposed along a sliding direction and/or a bending direction of the display unit DP. For example, when the display unit DP slides and/or is bent in the second direction DR2, the plurality of third reinforcement layers 633 extends along the second direction DR2. In the meantime, the plurality of third reinforcement layers 633 is not limited thereto, but may extend along the first direction DR1 to enclose the active area AA.

The plurality of third reinforcement layers 633 overlaps the cover window 190 in the third non-active area NA3. In one or more aspects, the plurality of third reinforcement layers 633 may cover a rear surface of the cover window 190 exposed in the third non-active area NA3.

In one or more aspects, edges of the plurality of third reinforcement layers 633 are disposed on the same plane as the edge of the cover window 190. For example, the plurality of third reinforcement layers 633 covers the rear surface of the cover window 190, but does not protrude to the outside of the third non-active area NA3 more than the cover window 190.

The plurality of third reinforcement layers 633 is in contact with an edge of the first adhesive layer AD1, an edge of the polarization plate 180, an edge of the second adhesive layer AD2, an edge of the display panel PN, an edge of the third adhesive layer AD3, an edge of the back plate 120, an edge of the fourth adhesive layer AD4, and edges of the plurality of first reinforcement layers 131. For example, the plurality of third reinforcement layers 633 covers the edge of the first adhesive layer AD1, the edge of the polarization plate 180, the edge of the second adhesive layer AD2, the edge of the display panel PN, the edge of the third adhesive layer AD3, the edge of the back plate 120, the edge of the fourth adhesive layer AD4, and the edges of the plurality of first reinforcement layers 131 which are exposed from the cover window 190.

The plurality of third reinforcement layers 633 is formed of a material different from that of the metal plate 110 and the back plate 120. For example, the plurality of third reinforcement layers 633 is formed of the same material as the plurality of first reinforcement layers 131.

In the display device 600 according to still another example embodiment of the present disclosure, the plurality of first reinforcement layers 131 which is disposed below the display panel PN and the back plate 120 and has a modulus equal to or larger than that of the back plate 120 is disposed to apply a stress to the display panel PN which does not cause the interlayer delamination. Accordingly, in the display device 600 according to still another example embodiment of the present disclosure, the interlayer delamination of the display panel PN is suppressed and the reliability of the display device 600 is improved.

Further, in the display device 600 according to still another example embodiment of the present disclosure, the first reinforcement layer 131 is disposed in the second non-active area NA2 in which the second adhesive layer AD2 is disposed with a large thickness. The neutral plane change which rapidly changes in the second non-active area NA2 is suppressed and the delamination problem of the display panel PN is minimized.

Further, in the display device 600 according to still another example embodiment of the present disclosure, the plurality of first reinforcement layers 131 is disposed without changing the design of the display panel PN to adjust the modulus of the display panel PN. Therefore, the problems, such as increase of the manufacturing cost of the display panel PN and increase of the repulsive force of the display panel PN, may be suppressed.

Further, in the display device 600 according to still another example embodiment of the present disclosure, the plurality of third reinforcement layers 633 which is formed of the same material as the plurality of first reinforcement layers 131 is disposed in the third non-active area NA3. Therefore, a level of stress which does not cause the interlayer delamination may be applied to the display panel PN. For example, the plurality of third reinforcement layers 633 is disposed below the cover window 190 to suppress the neutral plane of the display unit DP from being located to be adjacent to the cover window 190 in the third non-active area NA3. Therefore, when the display unit DP is bent to the direction which is opposite to the cover window 190, the plurality of third reinforcement layers 633 suppresses the tensile stress from being applied to the display panel PN. Further, even when the tensile stress is applied to the display panel PN, a tensile stress which does not cause the interlayer delamination of the display panel PN may be applied. Further, the plurality of third reinforcement layers 633 is disposed at the outer peripheral portion of the display unit DP to suppress the interlayer delamination problem from the outer peripheral portion of the display unit DP. Accordingly, the plurality of third reinforcement layers 633 suppresses a neutral plane change which rapidly changes in the third non-active area NA2 to minimize the delamination problem of the display panel PN.

Various examples and aspects of the present disclosure are described below. These are provided as examples, and do not limit the scope of the present disclosure.

According to an aspect of the present disclosure, a display device comprises a cover window, a flexible display panel disposed on a rear surface of the cover window, a metal plate disposed on a rear surface of the flexible display panel, and a plurality of first reinforcement layers which overlaps the cover window and is formed of a different material from the metal plate. A rear surface of the metal plate and rear surfaces of the plurality of first reinforcement layers may be disposed on the same plane.

The display device may further include a back plate disposed between the flexible display panel and the metal plate, the plurality of first reinforcement layers may overlap the back plate.

A modulus of the plurality of first reinforcement layers may be equal to or larger than a modulus of the back plate.

The back plate may be formed of polyimide or polyethylene terephthalate material and the plurality of first reinforcement layers may be formed of a resin material.

The plurality of first reinforcement layers may be in contact with an edge of the metal plate.

The flexible display panel further includes a display element and an organic encapsulation layer disposed on the display element, the organic encapsulation layer includes a first part having a flat top surface and a second part which encloses the first part and has an inclined top surface, and the plurality of first reinforcement layers may do not overlap the first part.

An edge of the flexible display panel may be exposed from the plurality of first reinforcement layers.

The display device may further include a plurality of second reinforcement layers which overlaps the first part on the same layer as the plurality of first reinforcement layers and is formed of a different material from the metal plate.

The plurality of second reinforcement layers may be in contact with the edge of the metal plate.

The display device may further include a plurality of third reinforcement layers which is in contact with the edges of the plurality of first reinforcement layers and an edge of the flexible display panel.

The plurality of third reinforcement layers may cover the rear surface of the cover window exposed from the flexible display panel.

The plurality of first reinforcement layers is disposed to be spaced apart from each other with the metal plate therebetween in a first direction, and the flexible display panel may be bent in a second direction.

The plurality of first reinforcement layers may enclose an edge of the metal plate.

According to another aspect of the present disclosure, a display device comprises a display panel which includes a display element, a first inorganic encapsulation layer which covers the display element, an organic encapsulation layer on the first inorganic encapsulation layer, and a second inorganic encapsulation layer on the organic encapsulation layer, a back plate disposed on a rear surface of the display panel, and a plurality of first reinforcement layers disposed on a rear surface of the back plate. The organic encapsulation layer may include a first part which has a flat top surface and a second part which encloses the first part and has an inclined top surface, and the plurality of first reinforcement layers does not overlap the first part.

A modulus of the plurality of first reinforcement layers may be equal to or larger than a modulus of the back plate.

The display device may further include a cover window which overlaps the plurality of first reinforcement layers on a top surface of the display panel, and a metal plate which is disposed on a rear surface of the display panel and is formed of a material different from the plurality of first reinforcement layers, a rear surface of the metal plate and rear surfaces of the plurality of first reinforcement layers may be disposed on the same plane.

The plurality of first reinforcement layers is disposed to be spaced apart from each other with the metal plate therebetween in a first direction, and the display panel may be bent in a direction which is opposite to the cover window in a second direction.

The display device may further include a plurality of second reinforcement layers which covers a rear surface of the back plate exposed between the metal plate and the plurality of first reinforcement layers and is formed of the same material as the plurality of first reinforcement layers.

The display device may further include a plurality of third reinforcement layers which is in contact with an edge of the back plate and an edge of the display panel exposed from the plurality of first reinforcement layers and is formed of the same material as the plurality of first reinforcement layers.

Edges of the plurality of third reinforcement layers may be disposed on the same plane as the edge of the cover window.

According to an aspect of the present disclosure, a display device comprises an active area, a first non-active area, a second non-active area, a display panel including a display element, and a plurality of first reinforcement layers disposed on a rear surface of the display panel. The display panel may be present in the active area, the first non-active area, and the second non-active area, and the plurality of first reinforcement layers may overlap the display panel in the second non-active area.

The display device may include a plurality of second reinforcement layers overlapping the display panel in the first non-active area.

The display device may include a plurality of third reinforcement layers disposed in a third non-active area and does not overlap the display panel.

The first non-active area is outside of the active area, and the second non-active area is outside of the first non-active area.

The first non-active area may at least partially or wholly enclose the active area, the second non-active area may at least partially or wholly enclose the first non-active area, and a third non-active area may at least partially or wholly enclose the second non-active area.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a cover window;
a flexible display panel disposed on a rear surface of the cover window;
a metal plate disposed on a rear surface of the flexible display panel; and
a plurality of first reinforcement layers which overlaps the cover window and is formed of a different material from the metal plate,
wherein a rear surface of the metal plate and rear surfaces of the plurality of first reinforcement layers are disposed on a same plane.

2. The display device according to claim 1, further comprising:
a back plate disposed between the flexible display panel and the metal plate,
wherein the plurality of first reinforcement layers overlaps the back plate.

3. The display device according to claim 2, wherein a modulus of the plurality of first reinforcement layers is equal to or larger than a modulus of the back plate.

4. The display device according to claim 3, wherein the back plate is formed of polyimide or polyethylene terephthalate material, and the plurality of first reinforcement layers is formed of a resin material.

5. The display device according to claim 1, wherein the plurality of first reinforcement layers is in contact with an edge of the metal plate.

6. The display device according to claim 1, wherein the flexible display panel further includes a display element and an organic encapsulation layer disposed on the display element,
wherein the organic encapsulation layer includes a first part having a flat top surface and a second part which encloses the first part and has an inclined top surface, and
wherein the plurality of first reinforcement layers does not overlap the first part.

7. The display device according to claim 6, wherein an edge of the flexible display panel is exposed from the plurality of first reinforcement layers.

8. The display device according to claim 7, further comprising:
a plurality of second reinforcement layers which overlaps the first part on a same layer as the plurality of first reinforcement layers and is formed of a different material from the metal plate.

9. The display device according to claim 8, wherein the plurality of second reinforcement layers is in contact with an edge of the metal plate.

10. The display device according to claim 7, further comprising:
a plurality of third reinforcement layers which is in contact with edges of the plurality of first reinforcement layers and an edge of the flexible display panel.

11. The display device according to claim 10, wherein the plurality of third reinforcement layers covers the rear surface of the cover window exposed from the flexible display panel.

12. The display device according to claim 1, wherein the plurality of first reinforcement layers is disposed to be spaced apart from each other with the metal plate therebetween in a first direction, and
the flexible display panel is bent in a second direction.

13. The display device according to claim 1, wherein the plurality of first reinforcement layers encloses an edge of the metal plate.

14. A display device, comprising:
a display panel which includes a display element, a first inorganic encapsulation layer which covers the display element, an organic encapsulation layer on the first inorganic encapsulation layer, and a second inorganic encapsulation layer on the organic encapsulation layer;
a back plate disposed on a rear surface of the display panel; and
a plurality of first reinforcement layers disposed on a rear surface of the back plate,
wherein the organic encapsulation layer includes a first part which has a flat top surface and a second part which encloses the first part and has an inclined top surface, and
wherein the plurality of first reinforcement layers does not overlap the first part.

15. The display device according to claim 14, wherein a modulus of the plurality of first reinforcement layers is equal to or larger than a modulus of the back plate.

16. The display device according to claim 15, further comprising:
a cover window which overlaps the plurality of first reinforcement layers on a top surface of the display panel; and
a metal plate which is disposed on a rear surface of the display panel and is formed of a material different from the plurality of first reinforcement layers,
wherein a rear surface of the metal plate and rear surfaces of the plurality of first reinforcement layers are disposed on a same plane.

17. The display device according to claim 16, wherein the plurality of first reinforcement layers is disposed to be spaced apart from each other with the metal plate therebetween in a first direction, and
wherein the display panel is bent in a direction which is opposite to the cover window in a second direction.

18. The display device according to claim 16, further comprising:
a plurality of second reinforcement layers which covers a rear surface of the back plate exposed between the metal plate and the plurality of first reinforcement layers and is formed of a same material as the plurality of first reinforcement layers.

19. The display device according to claim 16, further comprising:
a plurality of third reinforcement layers which is in contact with an edge of the back plate and an edge of the display panel exposed from the plurality of first reinforcement layers and is formed of a same material as the plurality of first reinforcement layers.

20. The display device according to claim 19, wherein edges of the plurality of third reinforcement layers are disposed on a same plane as an edge of the cover window.
